(19) United States
(12) Patent Application Publication
(10) Pub. No.: US 2004/0018750 A1
(43) Pub. Date: Jan. 29, 2004

(54) Method for deposition of nitrogen doped silicon carbide films

(76) Inventors: Auguste J.L. Sophie, Aloha, OR (US); Fumitoshi Ozaki, Tokyo (JP)

Correspondence Address: KNOBBE MARTENS OLSON & BEAR LLP, 2040 MAIN STREET, FOURTEENTH FLOOR, IRVINE, CA, 92614, US

(21) Appl. No.: 10/188,723

(22) Filed: Jul. 2, 2002

(51) Int. Cl. H01L 21/469; H01L 21/31; H01L 21/4763

(52) U.S. Cl. 438/792; 438/634

(57) ABSTRACT

Disclosed are processes for depositing a silicon carbonitride (Si—C—N) material and resulting films. The process involves plasma enhanced chemical vapor deposition (PECVD), in which chemical precursors for silicon and carbon are supported by nitrogen gas (N₂). Nitrogen gas not only supports the other chemical precursors and plasma species during the PECVD process, but also participates in the film formation. The nitrogen carrier gas is activated by plasma energy as other chemical precursors. Excited species of nitrogen gas react with excited species of silicon and carbon to deposit the Si—C—N material on a substrate. The use of nitrogen gas improves the stability of the plasma and eliminates arcing during the PECVD process. Further, the resulting Si—C—N material showed improved properties, such as less aging effects and improved thermal stability, as compared to processes using other carrier gases.

### BACKGROUND OF THE INVENTION

1. Field of the Invention

This invention relates generally to depositing films during integrated circuit fabrication and, more particularly, to depositing nitrogen-doped silicon carbide films.

2. Description of the Related Art

When fabricating integrated circuits, layers of insulating, conducting and semiconducting materials are deposited and patterned to produce desired structures. “Back end” or metallization processes include contact formation and metal line or wire formation. Contact formation vertically connects conductive layers through an insulating layer. Conventionally, contact vias or openings are formed in the insulating layer, which typically comprises a form of oxide, such as borophosphosilicate glass (BPSG), oxides formed from tetraethylorthosilicate (TEOS) precursors or newer low k materials. The vias are then filled with conductive material, thereby interconnecting electrical devices and wiring above and below the insulating layers. The layers interconnected by vertical contacts typically include horizontal metal lines running across the integrated circuit. Such lines are conventionally formed by depositing a metal layer over the insulating layer, masking the metal layer in a desired wiring pattern, and etching away metal between the desired wires or conductive lines.

Damascene processing involves forming trenches in the pattern of the desired lines, filling the trenches with a metal or other conductive material, and then etching or polishing the metal back to the insulating layer. Wires are thus left within the trenches, isolated from one another in the desired pattern. The etch-back process thus avoids more difficult photolithographic mask and etching processes of conventional metal line definition, particularly for copper metallization.

In an extension of damascene processing, a process known as dual damascene involves forming two insulating layers, typically separated by an etch stop material, and forming trenches in the upper insulating layer, as described above for damascene processing. Contact vias are etched through the floor of the trenches and the lower insulating layer to expose lower conductive elements where contacts are desired. As one of skill in the art will recognize, a number of processes are available for forming dual damascene structures. For example, trenches may be etched through the upper insulating layer, after which a further mask is employed to etch the contact vias. In another arrangement, a buried hard mask between the insulating layers defines the contact vias, and continued etching through the hard mask extends the vias from the trench floors. In an alternative embodiment, contact vias are first etched through the upper and lower insulating layers, after which the vias in the upper insulating layer are widened to form trenches with another mask.

Protective barriers are often formed between via or trench walls and metals in a substrate assembly, to aid in confining deposited material within the via or trench walls. These lined vias or trenches are then filled with metal by any of a variety of processes, including chemical vapor deposition (CVD), physical vapor deposition (PVD) and electroplating.

FIG. 1 illustrates a self-aligned dual damascene process in which an upper insulating layer 10 is formed over a lower insulating layer 12, which is in turn formed over a conductive wiring layer 14, preferably with an intervening barrier layer 15. This barrier layer 15 serves to reduce or prevent diffusion of copper or other conductive material from the underlying metal layer 14 into the overlying dielectric layer 12 and also serves as an etch stop during via formation.

A mask is employed to pattern and etch trenches 16 and contact vias 20 in a desired wiring pattern. In the illustrated embodiment, the trench 16 is etched down to the level of an etch stop layer 19, which is formed between the two insulating layers 10, 12. In the self-aligned dual damascene process this etch stop layer 19 is typically patterned and etched prior to deposition of the upper insulating layer 10 to form a buried hard mask that defines horizontal dimensions of desired contact vias that are to extend from the bottom of the trench 16. After the trenches 16 are etched through the upper insulating layer 10, continued etching through the hard mask 19 opens a contact via 20 from the bottom of the trench 16 to the lower conductive wiring layer 14. FIG. 1 also shows an upper etch stop or chemical mechanical polishing (CMP) stop layer 21 over the upper insulating layer 10 to stop a later planarization step, as will be appreciated by the skilled artisan. Once the trenches 16 and contact vias 20 are formed, they are typically lined with a barrier layer 22 and filled with copper or other conductive material 23 to make connection with the conductive wiring layer 14. Then, the copper or conductive material filling the trench 16 and contact via 20 is etched back (not shown) by polishing, leaving a metal line within the trench 16 and contact within via 20.

As described briefly above, the layers 15, 19, 21 in damascene processing typically act as a stop layer during dry-etch or CMP process steps. In acting as a stop layer, the etch stop prevents wear of the underlying insulation material and/or conductive material layers by an etch or CMP process. Furthermore, an etch stop layer may additionally serve as a diffusion barrier, preventing copper or other conductive material from diffusing into the insulation layers. These etch stop layers have traditionally been silicon nitride, particularly Si₃N₄. More recently, however, silicon carbide (SiC) and silicon oxycarbide (SiOC) have been employed.

The etch stop layers are typically deposited by plasma enhanced chemical vapor deposition (PECVD). PECVD is a species of chemical vapor deposition (CVD) techniques for depositing a desired material on a substrate using vapor phase chemical precursors. Generally, CVD techniques are conducted by supplying chemical precursors and allowing them to react with one another and the surface of the substrate to form a deposit on the substrate. The chemical precursors are activated by subjecting the chemical precursor to an amount of energy that is effective to decompose the precursor by breaking one or more chemical bonds. In PECVD, an electromagnetic field is applied to vapor phase chemical precursors to turn them to highly reactive species in a plasma phase. These activated species react with one another and the substrate to deposit a desired compositional material on the substrate.

### SUMMARY OF THE INVENTION

In accordance with one aspect of the invention, a method for depositing a silicon carbonitride (Si—C—N) material on a surface includes loading a substrate having a surface into a processing chamber. At least one chemical precursor and a carrier gas are introduced into the processing chamber, where the carrier gas includes nitrogen gas. An electromagnetic energy is applied to the at least one chemical precursor and the carrier gas, thereby depositing on the surface of the substrate the Si—C—N material

In accordance with another aspect of the invention, a method for forming a silicon carbonitride material by plasma enhanced chemical vapor deposition includes providing a substrate having a surface in a chamber. Excited species of elements comprising silicon species, carbon species and nitrogen species, are generated in a plasma supporting gas comprising nitrogen gas (N₂). The surface of the substrate is exposed to the excited species supported by the plasma supporting gas.

In accordance with another aspect of the invention, a process is provided for forming a layer comprising silicon and carbon in integrated circuit fabrication. The method includes introducing one or more chemical precursors, along with a carrier gas entraining the chemical precursors, into a chamber for plasma enhanced chemical vapor deposition (PECVD). The chemical precursors include silicon and carbon. PECVD is conducted in the chamber such that the carrier gas is activated to generate its own excited species, thereby depositing a layer comprising silicon, carbon and an element from the carrier gas on a substrate in a chamber.

### BRIEF DESCRIPTION OF THE DRAWINGS

These and other aspects of the invention will be readily apparent to the skilled artisan in view of the description below and the appended drawings, which are meant to illustrate and not to limit the invention, and in which:

FIG. 1 is a schematic cross-section of a dual damascene structure, illustrating etch stop layers at a point in the dual damascene process;

FIG. 2 schematically illustrates a deposition apparatus for use in PECVD in accordance with one embodiment of the present invention; and

FIGS. 3-7 are diagrams illustrating average deposition rates and various physical properties of the silicon carbonitride material deposited in accordance with one embodiment of the present invention.

### DETAILED DESCRIPTION OF THE PREFERRED EMBODIMENTS

The preferred embodiments of the present invention concerns deposition of Si—C—N material by plasma enhanced chemical vapor deposition (PECVD). In this disclosure, the term Si—C—N does not represent a chemical formula in the usual sense because it is not indicative of the overall stoichiometry of the material to which it refers. Si—C—N is a compositional material that contains at least the elements silicon, carbon and nitrogen, and may contain one or more additional elements. Si—C—N materials are referred to as “silicon carbonitride” or “silicon carbide doped with nitrogen.” Likewise, Si—C referred to as “silicon carbide” is a material that contains at least the elements silicon and carbon, and may contain one or more additional elements, such as nitrogen, such that Si—C—N is treated as a species of Si—C herein.

As discussed in the “Background” briefly, Si—C layers for use as a hard mask, etch stop or passivation layer have been deposited using PECVD processes. Typically, one or more chemical precursor gases are activated to form a plasma. Activated species from the chemical precursors react with each other at a substrate surface and form a Si—C film. In addition to the chemical precursor gases, a typical PECVD process utilizes a carrier gas. Generally, a carrier gas is a gas or a mixture of gases providing a flow to entrain chemical precursors en route to the PECVD chamber. The carrier gas also serves as a “plasma supporting gas” in the sense that it provides the appropriate gas density for igniting a plasma within the oscillating electric field. An inert or noble gas, such as helium, neon, argon, krypton or xenon, is often used as a carrier gas. For example, PECVD of Si—C films typically uses an inert gas to support chemical precursor molecules for Si and C elements. The inert gas does not participate in the film forming reactions with plasma species of chemical precursors.

The present inventors have discovered that when using a organosilicon precursor with an inert carrier gas, the plasma tends to be unstable and arcing occurs during the deposition. One possible explanation for the instability is that the inert carrier gas absorbs energy coupled to the gas for the activation of chemical species and then it discharges the energy by arcing, reducing efficiency of the PECVD process. Such arcing may also generate defects in deposited Si—C films. Furthermore, the Si—C films deposited even without arcing are relatively unstable, showing aging effects. After deposition, for example, during the first week thereafter, the refractive index and stress of the film significantly changes as a function of time.

In accordance with the preferred embodiment of the present invention, the PECVD for a Si—C—N hard mask, etch stop or passivation layer is carried out in the presence of diatomic nitrogen (N₂), which is alternatively referred to as “nitrogen gas.” The nitrogen gas serves as the carrier or plasma supporting gas in place of noble gas. The nitrogen carrier gas supports the chemical precursors and plasma species in the transportation and during the deposition of Si—C—N material. The nitrogen gas additionally serves as a chemical precursor for the nitrogen species. The nitrogen gas and chemical precursors are activated by a plasma energy to create a plasma composition including various N, C and Si species. Activated nitrogen species participate in the film formation by reacting with silicon and carbon species in the plasma. Preferably, the nitrogen gas is the only source of the nitrogen element in the resulting Si—C—N material.

The existence of the diatomic nitrogen carrier gas stabilizes the plasma, resulting in no arcing, or at least much less arcing, during the deposition, as compared to using noble gas carriers. In addition, the inventors have found that nitrogen incorporated in the deposited films provides the resulting films with stability while its existence in the film is not disadvantageous for the application of the film as a hard mask or passivation layer. The resulting films show reduced aging effects. For example, the refractive index of the film has smaller variations than Si—C film deposited using the same process with a noble carrier gas in place of nitrogen. Furthermore, the thermal stability of the film is improved.

Processes for forming Si—C—N layers are know in the art. Typically, however, conventional nitrogen sources are employed in a manner that allows ready modulation. Ammonia, for example, readily decomposes and altering the relative concentration of precursors affects the ratio of nitrogen incorporated when using conventional CVD with NH₃ as a precursor. In contrast, employing nitrogen as a carrier gas for PECVD is not so conducive to tailoring nitrogen concentration.

On the other hand, when using ammonia gas, the resulting layer may contain a large amount of hydrogen. The use of nitrogen gas according to the preferred embodiment of the present invention provides a more stable plasma than when using conventional plasma support gas (e.g., noble gases). Furthermore, the hydrogen content in the resulting material can be significantly reduced by use of nitrogen gas as a precursor instead of ammonia gas. Low hydrogen incorporation is preferred for the preparation of a hard mask or passivation layer. While the nitrogen content of the resultant films is not as controllable, the resultant films have been found suitable for etch stop layers.

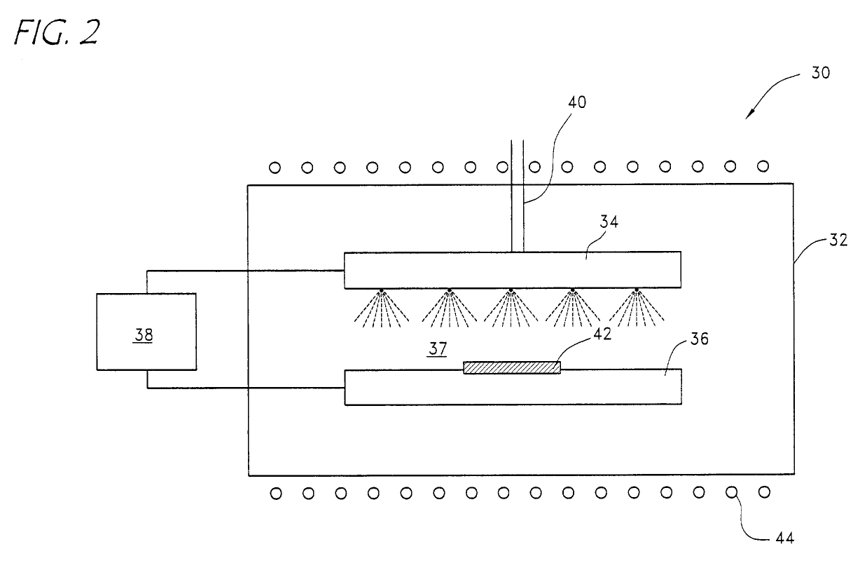

For purposes of illustration, FIG. 2 is a simplified view of an exemplary PECVD deposition system 30. This system 30 includes a processing chamber 32, which can be vacuum pumped to pressures suitable for supporting a plasma. In the chamber 32, two planar electrodes 34 and 36 are opposingly positioned and define a space 37 between them. These electrodes 34 and 36 are electrically connected to a plasma energy generator 38 located outside the chamber 32. The plasma energy generator 38 is preferably an RF generator. When the plasma energy generator 38 is turned on, a high-energy electromagnetic field is created in the space 37 between the electrodes 34 and 36. The lower electrode 36 is configured to receive one or more substrates 42 thereon. The lower electrode 36 preferably has a heating coil or heating block (not shown) inside it for heating the substrate 42 during the operation. A gas transporting line 40 is configured to transport gaseous chemical precursors into the chamber 32. The upper electrode 34 is preferably connected to the gas transporting line 40 to receive the gaseous chemical precursors. The upper electrode 34 preferably has a plurality of holes, through which the gaseous precursors from the gas transporting line 40 are emitted toward the substrate 42, as shown in dashed lines in FIG. 2. It will be understood that the reaction chamber can have a variety of other configurations. For example, the walls of the chamber can serve as one of the electrodes. Alternatively, other energy sources, such as inductive coupling, can provide the plasma energy. Also, the substrate can be radiantly heated or by an internally heated substrate element.

In operation, one or more semiconductor substrates 42 are loaded on the lower electrode 36 in the chamber 32. Preferably, the substrates 42 are placed such that only one surface of each substrate 42, on which the Si—C—N material is deposited, is exposed to the space 37. If needed, the chamber 32 is vacuum pumped to remove materials remaining in the chamber. The substrate 42 is heated to a desired temperature such as by internal heating of the wafer support or lower electrode 34. Walls of the chamber 32 are preferably also heated by the heating coil 44 to avoid contamination.

Once the system 30 is ready to carry out the PECVD deposition, a gaseous mixture of at least one chemical precursor and a carrier gas is introduced into the chamber 32. In the preferred embodiments of the present invention, the carrier gas is nitrogen gas (N₂). The at least one chemical precursor includes a silicon source gas and a carbon source gas. Preferably, a single chemical compound, such as an organosilicon gas, serves as both the silicon and carbon sources. When the gaseous mixture fills the chamber 32, the plasma energy generator 38 is turned on to create a high-energy electromagnetic field in the space 37 between the electrodes 34 and 36. The nitrogen gas and other precursor molecules in the space 37 are subject to the high energy of the electromagnetic field, which will break one or more chemical bonds in the molecules, forming a plasma state. The plasma state is known to include various activated species, such as ions and radicals, including species of N, Si and C elements and compounds. These activated species in the plasma state react with each other and/or with the substrate 42, thereby forming a layer of Si—C—N on the substrate 42.

As used herein, a “chemical precursor” is a chemical compound that contains the elements of silicon, carbon and/or nitrogen that can be activated or chemically reacted under the conditions described herein to form a Si—C—N material. Chemical precursors applicable herein include silicon-containing (Si-containing) chemical compounds; carbon-containing (C-containing) chemical compounds; nitrogen-containing (N-containing) chemical compounds; chemical compounds containing all three elements (Si—C—N containing); or chemical compounds containing both silicon and carbon (Si—C-containing), both silicon and nitrogen (Si—N-containing) or both carbon and nitrogen (C—N-containing).

As discussed herein, the nitrogen carrier gas preferably serves as a nitrogen source material as well as a carrier gas. Thus, N-containing chemical precursors herein includes nitrogen gas. Preferably, as also discussed elsewhere herein, the diatomic nitrogen carrier gas is the only N-containing chemical precursor with no additional N-containing chemical precursors. In other arrangements, one or more N-containing chemical precursors other than nitrogen gas may be added to supplement the nitrogen content during deposition of Si—C—N.

In a preferred embodiment, at least part of the silicon and carbon elements in the resulting Si—C—N material is supplied by a Si—C-containing or “organosilicon” chemical precursor, which may have one or more C—Si bonds. More preferably, a Si—C-containing chemical precursor provides substantially all of the silicon and carbon elements. In other arrangements, at least part of the silicon and carbon atoms are supplied by a mixture of a Si-containing chemical precursor and a separate C-containing chemical precursor. A variety of organosilicon compounds can be used as a Si—C source, with preferred examples including dimethylsilane, trimethylsilane and tetramethylsilane, with trimethylsilane (TMS) being particularly preferred.

Preferred Si-containing chemical precursors are includes chemicals of the formulas SiX₄, X₃SiSiX₃, X₃SiSiX₂SiX₃, SiXₙR₄₋ₙCXₙ, (X₃Si)₄₋ₙCXₙ, and (R₃₋ₙSiXₙ)₂O; wherein n is 0, 1, 2 or 3; wherein each X is individually selected from the group consisting of F, Cl, H and D; and wherein each R is individually selected from the group consisting of methyl, ethyl, phenyl and tertiary butyl. Si—C (as noted in previous paragraph) and Si—N containing precursors serve as Si-containing precursors because they contain silicon. Particular examples of Si-containing chemical precursors include SiH₄, Si₂H₆, Si₃H₈, SiF₄, SiCl₄, HSiCl₃, HSiBr₃, etc.

Preferred C-containing chemical precursors include chemicals of the formulas CₙH₂ₙ₊₂, CₙH₂ₙ Si—C (as noted above) or C—N containing precursors are species of C-containing precursors because they contain carbon. Particular examples of preferred C-containing chemical precursors include CH₄, C₂H₆, C₃H₈, C₄H₁₀ and C₂H₄.

In an embodiment where N-containing chemical precursors are provided in addition to the nitrogen carrier gas, N-containing chemical precursors are selected from the group consisting of RₘNX₃₋ₘ, X₂₋ₚRₚN—NRₚX₂₋ₚ, and XN═NX; wherein m is 0, 1 or 2; wherein p is 0 or 1; wherein each X is individually selected from the group consisting of F, Cl, H, and D; and wherein each R is individually selected from the group consisting of methyl, ethyl, phenyl and tertiary butyl. Non-limiting examples of preferred N-containing chemical precursors include NF₃, NCl₃, HN₃, F₂NNF₂, and FNNF.

Preferably, the chemical precursors can be readily provided in the form of a gas or vapor with a nitrogen gas as a carrier. In order to minimize contamination and produce a higher quality film, it is preferable to deposit the Si—C—N material onto the substrate by placing or disposing the substrate within a chamber and introducing the chemical precursor to the chamber. Use of a closed chamber is preferred because it permits the introduction of chemical precursors and the exclusion of undesirable species under controlled conditions. A liquid chemical precursor can be provided in vapor form by using a bubbler, e.g., by bubbling a carrier gas through the chemical precursor, or by using an evaporator.

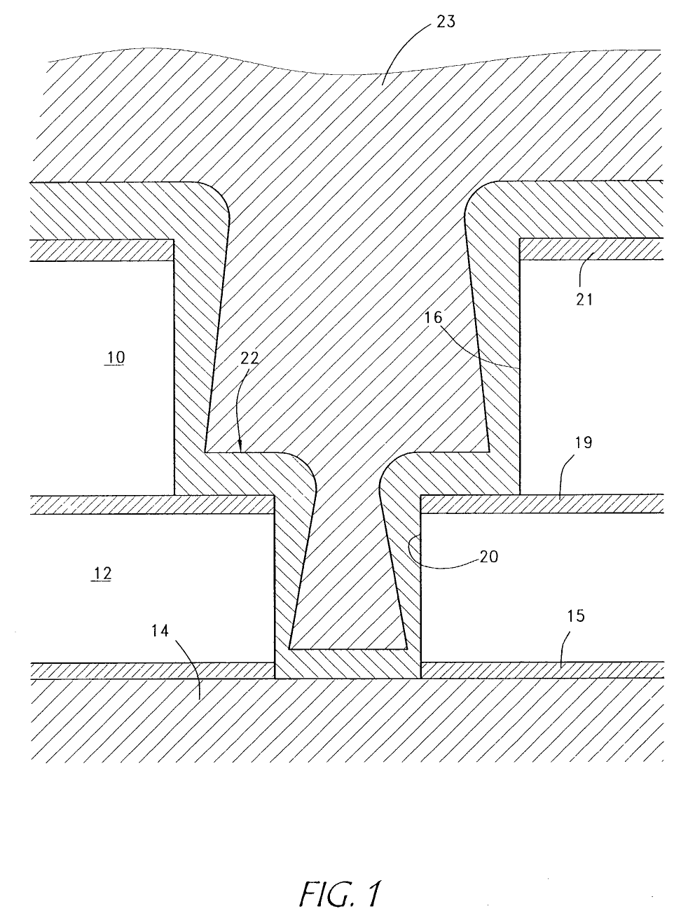

The Si—C—N is preferably deposited onto a substrate. “Substrate” is used in its usual sense to include any underlying surface onto which the Si—C—N material is deposited or applied. Preferred substrates can be made of virtually any material, including without limitation metal, silicon, germanium, plastic, and/or glass, preferably silicon, silicon compounds (including Si—O—C—H low dielectric constant films) and silicon alloys. Particularly preferred substrates include semiconductor substrates, e.g., silicon wafers and layers of Group III-V materials used in the fabrication of microelectronics, and integrated circuits. The term “integrated circuit” is used in its usual sense in the microelectronics field to include substrates onto which microelectronic devices have been or are to be applied, and thus includes integrated circuits that are in the process of being manufactured and which may not yet be functional. The substrates preferably subject to the PECVD process of the present invention include pre-fabricated structures, on which a Si—C—N will be deposited. More preferably, the top layer of the pre-fabricated structures is a conductive wiring layer (Cu) or an insulating (dielectric) layer, such that the deposited Si—C—N layer serves as one of the etch stop, barrier or hard mask layers depicted in FIG. 1.

In PECVD, plasma energy is used to activate the chemical precursor by applying an electromagnetic field, e.g., microwave or radio frequency energy to the chemical precursor(s). Preferably, the plasma energy is generated by an RF generator 38 operating at a frequency from about 400 kHz to about 40 MHz. The RF power at its high frequency, for example at 13.56 MHz, for reactors designed for processing 200 mm or 300 mm wafers, is preferably from about 100 W to about 1000 W, more preferably from about 150 W to about 750 W. For the same reactors, the high frequency can be set to 27.12 MHz, with preferred power levels of about 500 W to 5,000 W, more preferably about 3,000 W to 4,000 W. The RF power at its low frequency, for example at 430 kHz, is preferably from about 0 W to about 1000 W, more preferably from about 150 W to about 500 W. The high and low frequencies are mixed in the matching network during the deposition, as will be appreciated by those skilled in the art. The gap between the electrodes 34 and 36, as shown in FIG. 1, is preferably set with a range from about 3 mm to about 40 mm, more preferably from about 10 mm to about 25 mm.

Preferably, the PECVD deposition is carried out at an elevated temperature to facilitate film-forming reactions among the plasma species although the temperature is typically not as high as in thermal CVD. The chamber 32 is preferably equipped with a heating device like the heating coil 44 to preheat the chamber to a desired temperature. Alternatively, a heating device can pre-heat the substrate or its vicinity only. A preferred deposition temperature ranges from about 25° C. to about 650° C., more preferably from about 350° C. to about 450° C.

The amounts of nitrogen carrier gas and chemical precursor(s) are preferably controlled by adjusting the partial pressure or the flow rate of the gas. The amount can also be controlled by intermixing the chemical precursor(s) with the carrier gas and adjusting the total gas pressure or the partial pressure of the chemical precursor in the gas mixture. Preferably, a chamber is employed so that the flow of chemical precursor(s) can also be controlled by manipulating the overall pressure, using a vacuum pump or similar device. The flow of nitrogen gas ranges preferably from about 300 sccm to about 5.0 slm, more preferably from 1.0 slm to about 3.0 slm. The flow of the chemical precursor(s), for example an organosilane and more particularly trimethylsilane as a Si—C containing precursor, is controlled preferably in the range of from about 100 sccm to about 1 slm, more preferably from about 200 sccm to about 700 sccm. Preferred total pressures are in the range of about 200 Pa to about 800 Pa, more preferably about 400 Pa to about 600 Pa.

Suitable chambers for conducting PECVD are commercially available, and preferred models include the Eagle® series of reactors commercially available from ASM Japan K.K., of Tokyo, Japan. For example, the Eagle® 10 is designed for processing 200 mm wafers, while the Eagle® 12 is designed for 300 mm wafers. Commercially available PECVD chambers are preferably equipped with a number of features, such as computer control of temperature, gas flow and switching, and chamber pressure, that can be manipulated to produce consistently high-quality films suitable for microelectronics applications. Those skilled in the art are familiar with such methods and equipment, and thus routine experimentation may be used to select the appropriate conditions for depositing Si—C—N materials using the chemical precursors described herein.

As employed herein, Si—C—N materials are predominantly composed of the elements silicon, carbon and nitrogen. In the Si—C—N materials, the amount of nitrogen preferably ranges from about 5 wt. % to about 50 wt. %, more preferably about 10 wt. % to about 25 wt. %, most preferably about 15 wt. % to about 17 wt. %. The ratio of silicon to carbon atoms (Si:C) in Si—C—N materials is preferably in the range of about 1:2 to about 4:1, more preferably from about 1:1 to about 3:1. The Si—C—N materials can also be alloys that contain additional elements such as oxygen or hydrogen. The amount of the elements other than silicon, carbon and nitrogen is preferably less than about 5 atomic %, more preferably less than about 3 wt. %, most preferably between about 0 atomic % to about 1 atomic %.

The amount of nitrogen incorporated in the deposited material can vary. In the preferred embodiments where the nitrogen gas is the only nitrogen source, however, the nitrogen content in the resulting material tends not to substantially vary with various parameters of the PECVD process conditions, including partial pressure nitrogen gas. The amount of the nitrogen incorporation may, however, be adjusted by using an additional nitrogen source gas. Preferably, however, no additional source gases are employed; rather, a known process recipe for PECVD Si—C deposition is modified by substituting nitrogen gas (N₂) for a noble carrier gas. The inventors have found the resultant levels of nitrogen incorporation (in the most preferred ranges noted above) to be particularly advantageous for barrier and etch stop functionality and for improved film stability.

The composition of the other elements (particularly Si:C) can vary with respect to one another. In many cases, it may be desirable to provide a mixture of chemical precursors in order to deposit a film having the desired composition. Routine experimentation, using the following guidelines, may be used to select a suitable ratio of particular chemical precursors that together result in the deposition of a film having the desired chemical composition.

As a starting point, a precursor or mixture of precursors is preferably chosen that has an elemental composition that is relatively close to the desired relative composition of the silicon and carbon to be deposited. The weight percentage of each element in the precursor or precursor mixture can be readily calculated based on the molecular weight of the precursor and the weight of each precursor in the mixture.

Having chosen a starting precursor or mixture, an initial film can be deposited in the usual manner. In general, the elemental composition of this film will not be identical to the elemental composition of the starting precursor or mixture. For instance, the deposition temperature tends to affect hydrogen and halogen content, as well as the relative rates of precursor decomposition. After depositing the initial film, the starting precursor or mixture and/or process can be adjusted in an iterative fashion to produce a film having the desired composition. Preferably, experimental design methods are used to determine the effect of the various process variables and combinations thereof on chemical composition and/or physical properties of the resulting films. Experimental design methods per se are well known, see e.g., Douglas C. Montgomery, “Design and Analysis of Experiments,” 2^{nd} Ed., John Wiley and Sons, 1984. For a particular process, after the effect of the various process variables and combinations thereof on chemical composition and/or physical properties has been determined by these experimental design methods, the process is preferably automated by computer control to ensure consistency in subsequent production.

The relative composition of silicon and carbon in the deposited Si—C—N material can be adjusted or controlled by providing a supplemental source of an additional desired element or elements, preferably by providing a supplemental silicon source, nitrogen source, and/or carbon source. The supplemental source can be provided in various physical forms. Preferably, a gas is provided which simultaneously comprises the chemical precursor and the supplemental source(s), and the amount of each element in the resulting Si—C—N material is controlled by adjusting the partial pressure of each component using routine experimentation, in accordance with the guidance provided above. For example, as discussed above, the starting mixture of chemical precursor and supplemental source is preferably chosen to have a Si:C ratio that approximates the elemental composition of the deposited Si—C—N material, as modified by any knowledge of the effect of the particular deposition process chosen.

Among the supplemental sources, preferred silicon sources include silane, silicon tetrachloride, silicon tetrafluoride, disilane, trisilane, methylsilane, dimethylsilane, siloxane, disiloxane, dimethylsiloxane, methoxysilane, dimethoxysilane, and dimethyldimethoxysilane. Preferred supplemental nitrogen sources include ammonia, nitrogen trifluoride, nitrogen trichloride and nitrous oxide. Preferred carbon sources include methylsilane, disilylmethane, trisilylmethane and tetrasilylmethane. Preferred supplemental sources can be a source for two or more elements, e.g., dimethylsiloxane can be a source of carbon and silicon, etc. As noted above, however, the PECVD recipe most preferably employs only an organosilicon source and nitrogen carrier gas.

The Si—C—N materials described herein can be subjected to a variety of processes, e.g., patterned, etched, annealed, doped, etc. For example, in the manufacture of integrated circuits, additional layers of other materials such as dielectric layer, metal lines or semiconductor layers can be deposited onto the surface of a Si—C—N material formed as described herein. Such deposition can be conducted by providing various source materials and depositing the additional layer in the usual manner. The skilled artisan will readily appreciate that further processing to complete an integrated circuit will typically involve photolithography, etching, deposition, annealing and a variety of other steps.

The Si—C—N material produced according to the present invention can be in various forms such as particles or fibers, but is preferably in the form of a film. “Film” is used in its usual sense to include both freestanding films and layers or coatings applied to substrates. A film can be flat or it can conform to an underlying three-dimensional surface, and in either case can have a constant or variable thickness, preferably constant. Preferably, the average thickness of the film is effective to provide the desired function, e.g., etch stop, diffusion barrier, gate dielectric, passivation layer, spacer material, etc. Frequently, the average film thickness is in the range of about 100 Å to about 10,000 Å, preferably about 200 Å to about 5,000 Å, more preferably about 300 Å to about 3,000 Å.

The Si—C—N films described herein are useful for a variety of applications, particularly as a hard mask, etch stop layer, diffusion barrier, or passivation layer, more particularly in the dual damascene metallization context illustrated in FIG. 1.

### EXAMPLE 1

A Si—C—N film was deposited by a PECVD process according to an embodiment of the present invention. In this example, trimethylsilane was used as an organosilicon chemical precursor for both silicon and carbon. Nitrogen gas (N₂) was used as the carrier gas. The process conditions were: trimethylsilane flow=300 sccm, N₂ flow=1.8 slm, P=500 Pa, high frequency RF power (13.56 MHz)=300 W, low frequency RF power (430 kHz)=300 W, T=420° C., electrode gap=14 mm. This process was carried out in an Eagle®10 PECVD apparatus using a 200 mm wafer.

The film deposited was analyzed by X-ray Photoelectron Spectroscopy (XPS). The composition of the deposited film was as follows: Si=46 at %, C=35 at %, N=17 at %, and O=2 at %. The compressive stress of this film was measured to be about 150 MPa. This film stress did not change substantially over 120 hours. The refractive index for the deposited film was measured to be 1.97, but was more generally found dependent upon film thickness.

### EXAMPLE 2

Si—C—N films were deposited 200 mm wafers, using an Eagle® 10 PECVD apparatus in accordance with an embodiment of the present invention. Process conditions were varied while the temperature and electrode gap were set to 400° C. and 15 mm, respectively. The varying process conditions included trimethylsilane flow, nitrogen flow, reactor pressure, high frequency RF power and low frequency RF power.

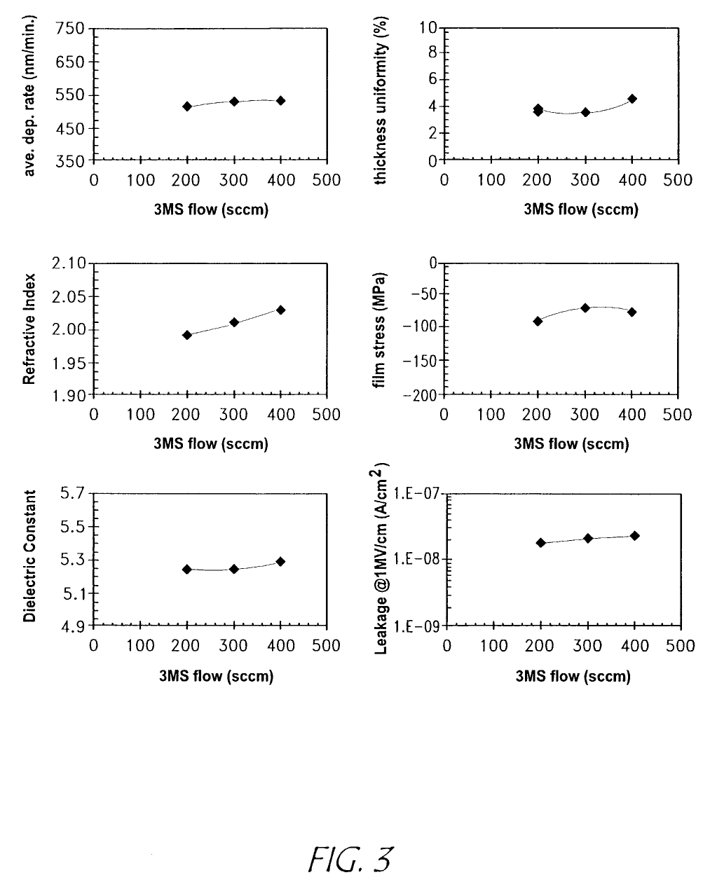

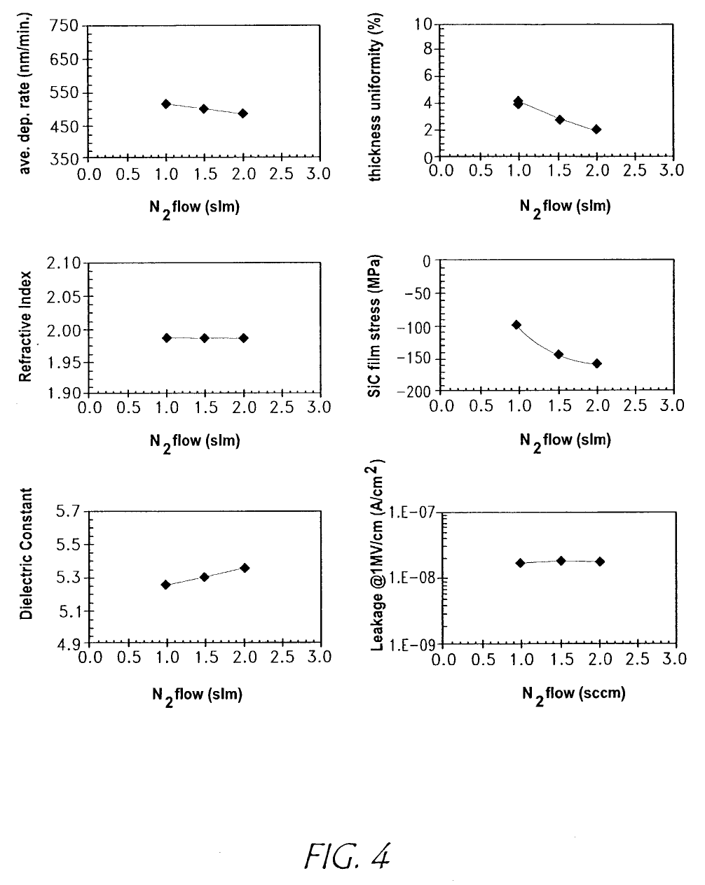

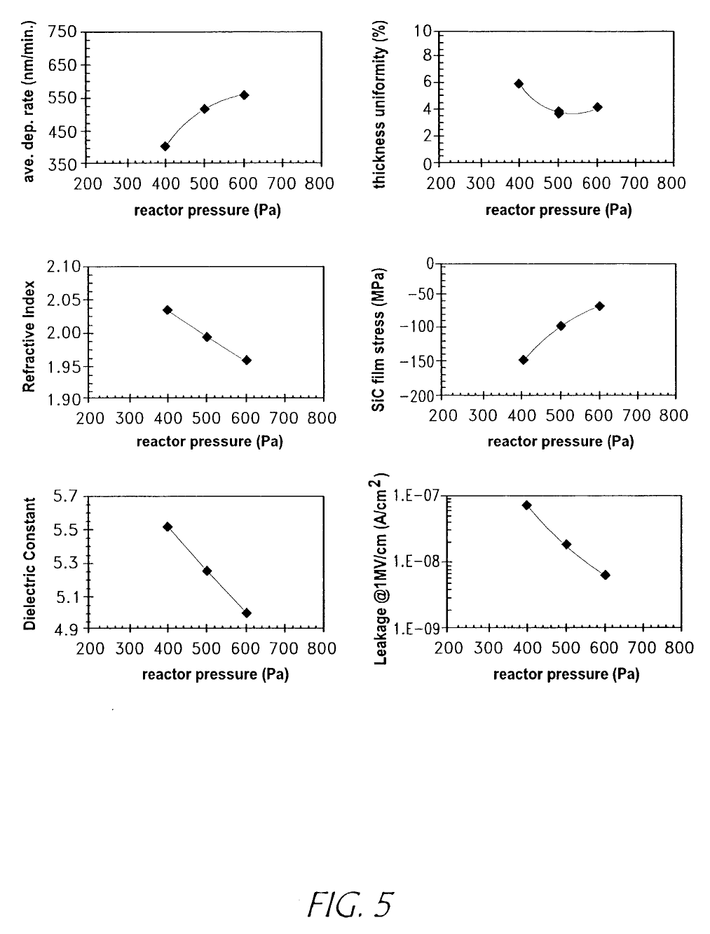

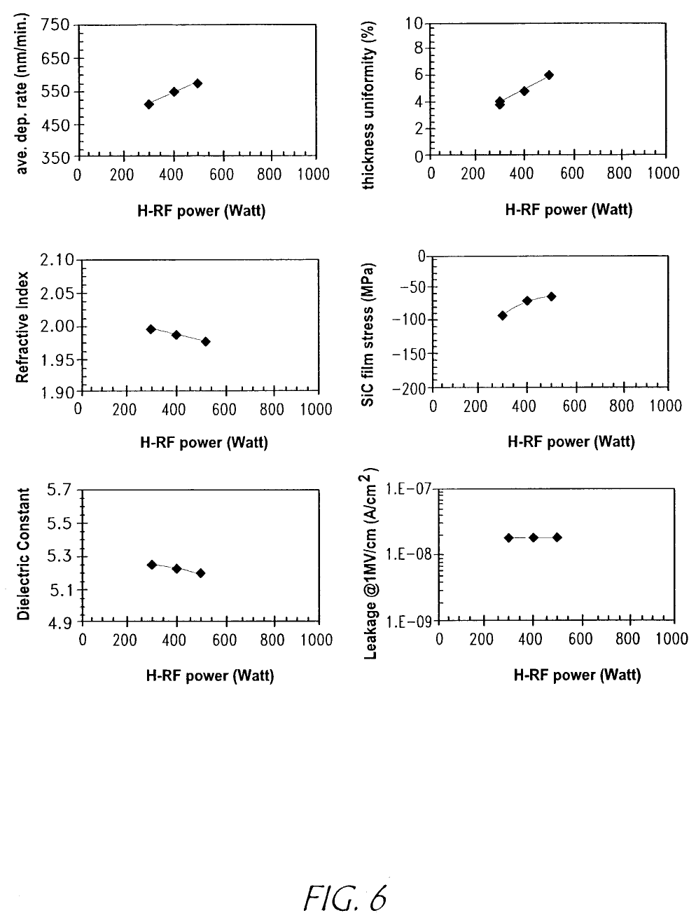

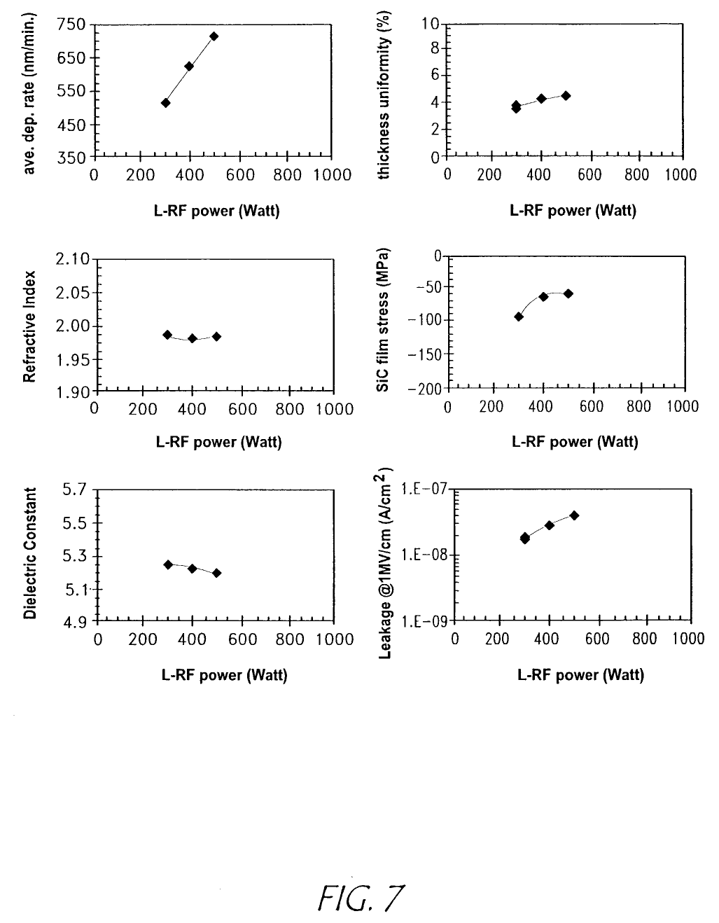

Average deposition rates, thickness uniformity, refractive index, film stress, dielectric constant and leakage current of the films were measured and are shown in FIGS. 3-7. FIG. 3 represents depositions with trimethylsilane flow at 200, 300 and 400 sccm while other conditions are set to: nitrogen flow=1.0 slm, P=500 Pa, high frequency RF power (13.56 MHz)=300 W and low frequency RF power (430 kHz)=300 W. FIG. 4 represents depositions with nitrogen flow at 1.0, 1.5 and 2 slm while other conditions are set to: trimethylsilane flow=200 sccm, P=500 Pa, high frequency RF power=300 W and low frequency RF power=300 W. FIG. 5 represents depositions with the reactor pressure are at 400, 500 or 600 Pa while others are set to: trimethylsilane (3MS) flow=200 sccm, nitrogen flow=1.0 slm, high frequency RF power=300 W and low frequency RF power=300 W. FIG. 6 represents depositions with varying high frequency RF power while others are set to: trimethylsilane flow=200 sccm, nitrogen flow=1.0 slm, P=500 Pa and low frequency RF power=300 W. In FIG. 7, the low frequency RF power varies while others are set to: trimethylsilane flow=200 sccm, nitrogen flow=1.0 slm, P=500 Pa and high frequency RF power=300 W.

It will be understood by those of skill in the art that numerous and various modifications can be made without departing from the spirit of the present invention. Therefore, it should be clearly understood that the various embodiments discussed above and described in the examples below are illustrative only and are not intended to limit the scope of the present invention.

We claim:

1. A method for depositing a silicon carbonitride (Si—C—N) material on a surface, comprising:
loading a substrate having a surface into a processing chamber;
introducing at least one chemical precursor and a carrier gas into the processing chamber, the carrier gas comprising nitrogen gas; and
applying an electromagnetic energy to the at least one chemical precursor and the carrier gas, thereby depositing on the surface of the substrate a Si—C—N material comprising silicon, carbon and nitrogen.

2. The method of claim 1, wherein the electromagnetic energy is sufficient to activate molecules of the at least one chemical precursor and carrier gas to create a plasma state.

3. The method of claim 1, wherein substantially all of the nitrogen contained in the deposited material originates from the nitrogen gas.

4. The method of claim 1, wherein the at least one chemical precursor includes a chemical precursor for silicon and a chemical precursor for carbon.

5. The method of claim 4, wherein the chemical precursor for silicon is selected from the group consisting of SiH₄, Si₂H₆, Si₃H₈, SiF₄, SiCl₄, SiCl₃ and HSiBr₃.

6. The method of claim 4, wherein the chemical precursor for carbon is one or more selected from the group consisting of CH₄, C₂H₆, C₃H₈, C₄H₁₀ and C₂H₄.

7. The method of claim 1, wherein the at least one chemical precursor is a single chemical compound comprising silicon and carbon elements.

8. The method of claim 6, wherein the single chemical compound is selected from the group consisting of methylsilane, dimethylsilane, trimethylsilane and tetramethylsilane.

9. A silicon carbonitride (Si—C—N) material deposited on a substrate according to the method of claim 1.

10. A method for forming a silicon carbonitride material by plasma enhanced chemical vapor deposition, comprising:
providing a substrate having a surface in a chamber; and
generating excited species of elements comprising silicon species, carbon species and nitrogen species, wherein the generated species are supported by a plasma supporting gas comprising nitrogen gas (N₂), and wherein the surface of the substrate is exposed to the excited species supported by the plasma supporting gas.

11. The method of claim 10, wherein the excited species are generated near the surface of the substrate.

12. A process for forming a layer comprising silicon and carbon in integrated circuit fabrication, comprising:
introducing into a chamber for plasma enhanced chemical vapor deposition (PECVD) one or more chemical precursors comprising silicon and carbon along with a carrier gas entraining the chemical precursors into the chamber; and
carrying out the PECVD in the chamber such that the carrier gas is activated to generate its own excited species, thereby depositing a layer comprising silicon, carbon and an element from the carrier gas on a substrate in a chamber.

13. The process of claim 12, wherein the element from the carrier gas is nitrogen.

14. The process of claim 13, wherein the carrier gas comprises nitrogen gas.
